(19) United States
(12) Patent Application Publication
(10) Pub. No.: US 2021/0136922 A1
(43) Pub. Date: May 6, 2021

(54) ULTRAMICRO CIRCUIT BOARD BASED ON ULTRATHIN ADHESIVELESS FLEXIBLE CARBON-BASED MATERIAL AND PREPARATION METHOD THEREOF

(71) Applicant: SHENZHEN DANBOND TECHNOLOGY CO., LTD, Shenzhen (CN)

(72) Inventors: Ping LIU, Shenzhen (CN); Fan XIE, Shenzhen (CN); Shuangqing ZHANG, Shenzhen (CN); Ting LI, Shenzhen (CN)

(21) Appl. No.: 17/083,276

(22) Filed: Oct. 28, 2020

(30) Foreign Application Priority Data
Oct. 30, 2019 (CN) 201911047676.5

(51) Int. Cl. H05K 3/02; H05K 1/03; H05K 1/09; H05K 3/00; C23C 16/02; C23C 16/56; H01Q 1/38

(52) U.S. Cl. CPC H05K 3/027; H01Q 1/241; H05K 1/09; H05K 3/0055; H05K 3/022; C23C 16/0227; C23C 16/56; H01Q 1/38; H05K 2201/0129; H05K 2201/0154; H05K 2201/0323; H05K 2201/10098; H05K 2203/087; H05K 2203/095; H05K 2203/107; H05K 1/0373

(57) ABSTRACT

An ultramicro circuit board based on an ultrathin adhesiveless flexible carbon-based material and a preparation method thereof. The method comprises the steps of: S1. depositing to form a PI film on a surface of a quantum carbon-based film through a chemical vapor deposition (CVD) reaction, and manufacturing a flexible circuit board base material with a quantum carbon-based film/PI double-layer composite structure; and S2. manufacturing a high-frequency ultramicro circuit antenna on the flexible circuit board base material through a laser scanning etching method. The preparation method has the advantages of being good in environmental friendliness, high in efficiency, low in manufacturing cost and the like, and the manufactured antenna ultramicro circuit board has the advantages of being high in thermal and electrical conductivity, ultra-flexible, low in dielectric, low in loss and high in shielding performance, which can be applied to 5G equipment.

### CROSS REFERENCE TO RELATED APPLICATION

This application claims priority to CN patent application NO. 201911047676.5 filed on 2019 Oct. 30. The contents of the above-mentioned application are all hereby incorporated by reference.

### BACKGROUND OF THE INVENTION

### 1. Field of the Invention

The invention relates to an ultramicro circuit board based on an ultrathin adhesiveless flexible carbon-based material and a preparation method thereof.

### 2. Description of the Prior Art

A flexible printed circuit board (FPC) mainly consists of a flexible insulating base film and a metal foil. It is commonly formed by bonding the insulating base film and the metal copper foil with an adhesive. The typical flexible substrate material is flexible copper clad laminate (FCCL), which is an important base material for FPC manufacture in the past decades with its market rapidly expanding. With the development trend of ultra-thin, flexible, highly integrated and multi-functional electronic instruments, the number of I/O terminals of a CPU chip becomes larger and larger, and the wiring width and spacing of a FPC corresponding to the number of I/O terminals are also sharply narrowed. As the Joule calorific value is increased to generate high temperature, especially when a large amount of Joule heat is generated when large current flows through a circuit, the conventional FPC with the FCCL as a flexible circuit board base material can generate circuit fusing risk due to the problem of poor thermal conductivity. On the other hand, with the advent of the 5G high-speed and high-frequency communication era, the emerging markets, such as artificial intelligence and Internet of Things, have posed higher challenges to the traditional PCB and FPC industries. The need for a circuit board base material with high frequency, high speed, high thermal conductivity, and high shielding performance has become an urgent task.

The disclosure of the above background art is only used for assisting in understanding the inventive concept and technical solution of the present invention, and does not necessarily belong to the prior art of the present patent application. Insofar as there is no explicit evidence that the above-mentioned contents have been disclosed on the filing date of the present patent application, the above-mentioned background art should not be used for evaluating the novelty and inventive step of the present application.

### SUMMARY OF THE INVENTION

The present invention mainly aims to overcome the defects in the prior art, and provides an ultramicro circuit board based on an ultrathin adhesiveless flexible carbon-based material and a preparation method thereof.

In order to achieve the above object, the present invention adopts the following technical solution:

A preparation method of an ultramicro circuit board based on an ultrathin adhesiveless flexible carbon-based material, comprises the steps of:

S1. depositing to form a PI film on a surface of a quantum carbon-based film through a chemical vapor deposition (CVD) reaction, and manufacturing a flexible circuit board base material with a quantum carbon-based film/PI double-layer composite structure; and

S2. manufacturing a high-frequency ultramicro circuit antenna on the flexible circuit board base material through a laser scanning etching method.

Further:

when the high-frequency ultramicro circuit antenna is manufactured in the step S2, the laser energy density is controlled to be 0.5-1.0 J/cm², preferably 0.8 J/cm², and the laser scanning speed is controlled to be 50-300 mm/s, preferably 100 mm/s; preferably, the circuit line width/line spacing is 5 nm/5 nm; preferably, an antenna ultramicro circuit is etched in alignment by rapidly moving a beam through a scanning galvanometer, and non-contact analog imaging is employed.

Before the step S1, the preparation method further comprises the steps of manufacturing the quantum carbon-based film:

S01. hybridizing anhydride containing phenyl with diamine to obtain a thermoplastic polyimide resin precursor;

S02. preparing a polyimide thin film by using the thermoplastic polyimide resin precursor;

S03. carbonizing and blackleading the polyimide thin film, doping nano-metal to the polyimide thin film, and performing ion implantation and ion exchange, wherein a nano monoclinic crystal phase in the film is changed into a tetragonal crystal, and the single crystal is changed into a superlattice; and

S04. performing high-temperature annealing treatment on the material obtained in the step S03 to generate a super-flexible ultra-thin compound semiconductor film.

In step S02, a diamino dianthryl ether is used for gel synthesis with the thermoplastic polyimide resin precursor, and a blowout type spraying method is used for uniformly forming a film to obtain a heterogeneous hybridized polyimide thin film; preferably, the gel synthesis is performed above −100° C., preferably the diamino dianthryl ether has a hybridized molecular weight greater than 1,000,000.

In the step S03, when dehydrogenating and denitrifying during blackleading, nano-metal is doped with a protective gas at a pressure of 50 Kpa, and the nano-metal is selected from Al, Ga, In and Ge, preferably from Ga, In and Ge, with a particle size of 1,000 nm or less, preferably 400 nm or less.

In step S04, an annealing process is performed at a temperature not lower than 3,200° C. to make a base film material expand, deoxidize and replace, transform crystal phase change to meet the high-orientation requirement of the superlattice.

Step S1 comprises: firstly, performing plasma modification treatment on the surface of the quantum carbon-based film, preferably argon plasma, and generating an acrylic acid grafted layer on a surface of the quantum carbon-based film through a grafting reaction; depositing on the surface of the quantum carbon-based film to form the PI film;

preferably, the plasma treatment discharge power is 20-150 W, the working air pressure is 10-100 Pa, and the treatment time is 5-30 min; preferably, the discharge power is 70 W, the working pressure is 70 Pa, and the treatment time is 15 min;

preferably, generating the acrylic graft layer comprises: immersing the quantum carbon-based film subjected to plasma treatment into an acrylic acid solution with a volume concentration of 2%-10% for grafting reaction; preferably, the concentration of the acrylic acid solution is 4%; preferably, the surface of the film is rinsed with distilled water after being immersed in the acrylic acid solution and heated in a 40° C. water bath for 5-6 h, then the film is immersed in distilled water, and after being heated in a 60° C. water bath for 24 h, the quantum carbon-based film is vacuum dried.

Step S1 further comprises: performing rapid thermal treatment on the formed PI film to completely imidize the PI film and eliminate an internal stress of the PI film; preferably, performing rapid thermal treatment on the freshly deposited PI film in a rapid thermal annealing (RTA) furnace in an inert gas atmosphere, preferably nitrogen, for 10 min at a thermal treatment temperature of 200-350° C.

In step S1, depositing to form the PI film comprises: alternately depositing a monomer dianhydride precursor and a monomer diamine precursor on the surface of the quantum carbon-based film, and performing cyclic deposition, wherein the thickness of the deposited film is controlled by controlling the number of cycles of deposition; preferably, the monomeric dianhydride precursor is one or a combination of several of 3,3′,4,4′-biphenyltetracarboxylic dianhydride, 2,3,3′,4′-diphenyl ether tetracarboxylic dianhydride, 3,3′,4,4-diphenyl ether tetracarboxylic dianhydride, and 2,2-bis (3,4-dicarboxyphenyl) hexafluoropropionic dianhydride; the monomeric diamine precursor is one or a combination of several of m-phenylenediamine, p-phenylenediamine, 3,3′-diaminodiphenyl ether, 3,4′-diaminodiphenyl ether, 3,3′-diaminotoluene, 3,3′-diaminediphenyl sulfone and 4,4′-diamine diphenyl sulfone;

preferably, one deposition cycle comprises the steps of:

S11. sending the evaporated monomer dianhydride precursor to the surface of the quantum carbon-based film in the form of an inert gas pulse, preferably nitrogen pulse for a pulse period of 1.5-7.0 s, preferably 3.0 s, and at a reactor pressure of 2-3 mbar; and

S12. sending the evaporated monomer diamine precursor to the surface of the quantum carbon-based film in the form of an inert gas pulse, preferably nitrogen pulse, and reacting with a dianhydride precursor which is chemisorbed on the surface of the quantum carbon-based film for a pulse time of 1.0-5.0 s, preferably 2.0 s, and at a reactor pressure of 2-3 mbar;

more preferably, after steps S11 and 12, an inert gas purge, preferably nitrogen, is performed before the next step, preferably the purging time is 1.5-3.0 s.

An ultramicro circuit board based on an ultrathin adhesiveless flexible carbon-based material, is an ultramicro circuit board prepared by using the method.

The present invention has the following beneficial effects:

The invention provides an ultramicro circuit board based on an ultrathin adhesiveless flexible carbon-based material and a preparation method thereof. The flexible carbon-based film is used as a substrate, chemical vapor deposition (CVD) is performed on the quantum carbon-based film, and a flexible circuit board base material with a quantum carbon-based film/PI (for example, 20 μm/20 μm) double-layer composite structure is manufactured. The flexible circuit board base material is an ultra-thin adhesiveless flexible carbon-based material, and is a novel base material that can replace a traditional FPC base material FCCL (flexible copper clad laminate) to manufacture an antenna ultra-micro circuit board. The conductor copper foil layer in the traditional FCCL can be replaced by flexible quantum carbon-based film replaces, and the carbon-based circuit board manufactured by using the flexible circuit board base material has the advantages of good thermal and electrical conductivity, large specific heat, excellent heat resistance, low temperature rises when large current passes, no fusing of circuit devices, with greatly improved reliability, at the same time, the excellent electromagnetic shielding performance is good, which can well meet the requirement of 5G communication equipment. Dry etching circuit is performed through a laser method, an ultrafast laser processing system is adopted to rapidly move light beams through a scanning galvanometer to realize alignment etching of an antenna ultramicro circuit, non-contact analog imaging is adopted to rapidly process, and a high-frequency antenna ultramicro circuit board is obtained. The process has the advantages of being good in environmental friendliness, high in efficiency, low in manufacturing cost and the like, and the manufactured antenna ultramicro circuit board has the advantages of being low in dielectric, low in loss and high in shielding performance, which can be applied to 5G equipment, and is particularly used for manufacturing products of 5G and next generation Wi-Fi technologies with high frequency, high shielding, low power consumption and low cost.

In a preferred embodiment, the flexible circuit board base material of the manufactured quantum carbon-based film/PI (20 μm/20 μm) double-layer composite structure is a C-C-FPC flexible circuit substrate or a C-C-FCCL substrate material having high electrical conductivity, ultra-flexibility, high thermal conductivity and high frequency characteristics.

Further advantages can be obtained in the preferred embodiment, for example, the preparation process of the quantum carbon-based film uses ion implantation and ion exchange, doping the nano transition metal, doping the nano transition metal with a protective gas at a gas pressure of 50 Kpa, and high-temperature annealing treatment, and the final material has excellent properties of high specific surface area, low resistance, high conductivity and high carrier mobility, high carrier concentration, high thermal conductivity, thermal resistance and the like, and the carbon element phase is changed from a single crystal to a superlattice and transits from one axis to two axes, so that the super flexibility of the base material is realized. Specific advantages will be described in further detail in connection with the embodiments.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

none

### DETAILED DESCRIPTION

Hereinafter, embodiments of the present invention will be described in detail. It should be emphasized that the following description is exemplary only and is not intended to limit the scope of the invention and application thereof.

In one embodiment, a preparation method of an ultramicro circuit board based on an ultrathin adhesiveless flexible carbon-based material, comprises the steps of:

S1. depositing to form a PI film on a surface of a quantum carbon-based film through a chemical vapor deposition (CVD) reaction, and manufacturing a flexible circuit board base material with a quantum carbon-based film/PI double-layer composite structure; and

S2. manufacturing a high-frequency ultramicro circuit antenna on the flexible circuit board base material through a laser scanning etching method.

The flexible carbon-based film is used as a substrate, chemical vapor deposition (CVD) is performed on the quantum carbon-based film, and a flexible circuit board base material with a quantum carbon-based film/PI (for example, 20 μm/20 μm) double-layer composite structure is manufactured. The flexible circuit board base material is an ultra-thin adhesiveless flexible carbon-based material, and is a novel base material that can replace a traditional FPC base material FCCL (flexible copper clad laminate) to manufacture an antenna ultra-micro circuit board. The conductor copper foil layer in the traditional FCCL can be replaced by flexible quantum carbon-based film replaces, and the carbon-based circuit board manufactured by using the flexible circuit board base material has the advantages of good thermal and electrical conductivity, large specific heat, excellent heat resistance, low temperature rises when large current passes, no fusing of circuit devices, with greatly improved reliability, at the same time, the excellent electromagnetic shielding performance is good, which can well meet the requirement of 5G communication equipment.

In a preferred embodiment, when the high-frequency ultramicro circuit antenna is manufactured in the step S2, the laser energy density is controlled to be 0.5-1.0 J/cm², preferably 0.8 J/cm², and the laser scanning speed is controlled to be 50-300 mm/s, preferably 100 mm/s; preferably, the circuit line width/line spacing is 5 nm/5 nm; preferably, an antenna ultramicro circuit is etched in alignment by rapidly moving a beam through a scanning galvanometer, and non-contact analog imaging is employed.

Dry etching circuit is performed through a laser method, an ultrafast laser processing system is adopted to rapidly move light beams through a scanning galvanometer to realize alignment etching of an antenna ultramicro circuit, non-contact analog imaging is adopted to rapidly process, and a high-frequency antenna ultramicro circuit is obtained. The process has the advantages of being good in environmental friendliness, high in efficiency, low in manufacturing cost and the like, and the manufactured antenna ultramicro circuit has the advantages of being low in dielectric, low in loss and high in shielding performance, which can be applied to 5G equipment, and is particularly used for manufacturing products of 5G and next generation Wi-Fi technologies with high frequency, high shielding, low power consumption and low cost.

In a preferred embodiment, before the step S1, the preparation method further comprises the steps of manufacturing the quantum carbon-based film:

S01. hybridizing anhydride containing phenyl with diamine to obtain a thermoplastic polyimide resin precursor;

S02. preparing a polyimide thin film by using the thermoplastic polyimide resin precursor;

S03. carbonizing and blackleading the polyimide thin film, doping nano-metal to the polyimide thin film, and performing ion implantation and ion exchange, wherein a nano monoclinic crystal phase in the film is changed into a tetragonal crystal, and the single crystal is changed into a superlattice; and

S04. performing high-temperature annealing treatment on the material obtained in the step S03 to generate a super-flexible ultra-thin compound semiconductor film.

The preparation method of the flexible carbon-based film provided by the preferred embodiment, a thermoplastic polyimide resin precursor is obtained by hybridizing anhydride containing phenyl and diamine, a high-density polyimide film is prepared from the precursor, preferably, a high-density thick film is prepared with double-inclined heterogeneous hybridized polyimide having high heat resistance and degree of freedom by adopting a chemical spraying method; Carbonization and blackleading high-temperature process are performed on the obtained polyimide thin film, and ion implantation and ion exchange are performed by doping a nano-metal material to change the nano monoclinic crystal phase into a tetragonal crystal; and the high-temperature annealing process is optimized to make a base film material expand, deoxidize and replace, make the metal nano-element liquid crystalline phase change and the defect crystal boundary reduce, so as to ensure that the layered plane direction is aligned with the vertical direction and has higher orientation performance, the superlattice is oriented more than 87%, thus the van der waals force is optimized. The experimental results show that the compound semiconductor material C-C-X with band gap of 2.3 EV, carrier concentration of 1.6×10²⁰ cm⁻³, resistivity of 2.310E-04 (Ω·m/cm), high temperature, high voltage, high frequency performance, large width of 920-1,200 mm, super-flexible, ultra-thin layer microstructure can be obtained by the preparation method of the present invention.

In step S01, hybridizing anhydride containing phenyl with diamine to obtain a thermoplastic polyimide resin precursor. The specific method may be referred to the method disclosed in the applicant's prior patent application CN 109776826 A. Step S01 of the preferred embodiment comprises:

dissolving 30-60 parts by volume of 2,2-bis [4-(4-aminophenoxy) phenyl]propane (BAPP), 30-60 parts by volume of 4,4′-diaminodiphenyl ether (4,4′-ODA) and 7-14 parts by volume of diamino dianthryl ether (also known as heterodiamine, the structural formula is

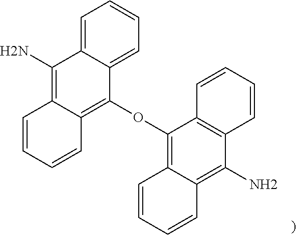 [SMILES: Nc1c2ccccc2c(Oc2c3ccccc3c(N)c3ccccc23)c2ccccc12]

in N, N-dimethylformamide (DMF), adding 30-60 parts by volume of 3,3′,4,4′-benzophenone tetracarboxylic dianhydride (BTDA), then adding 20-40 parts by volume of pyromellitic dianhydride (PMDA), after a period of reaction, additionally adding 3,3′,4,4′-benzophenone tetracarboxylic dianhydride (BTDA) and/or pyromellitic dianhydride (PMDA) and obtaining a polyimide resin precursor with thermoplasticity, heat resistance and freedom degree.

In a more preferred embodiment, in step S1, the total number of moles of 3,3′,4,4′-benzophenone tetracarboxylic dianhydride (BTDA) and pyromellitic dianhydride (PMDA) is made approximately equal to the total moles of 2,2-bis [4-(4-aminophenoxy) phenyl]propane (BAPP), 4,4′-diaminodiphenyl ether (4,4′-ODA) and diamino dianthryl ether.

In a preferred embodiment, in step S2, a diamino dianthryl ether is used for gel synthesis with the thermoplastic polyimide resin precursor, and a blowout type spraying method is used for uniformly forming a film to obtain a heterogeneous hybridized polyimide thin film.

In a more preferred embodiment, in step S2, the gel synthesis is performed above −100° C. Preferably the diamino dianthryl ether has a hybridized molecular weight greater than 1,000,000.

In step S02, a diamino dianthryl ether is used for gel synthesis with the thermoplastic polyimide resin precursor, and a blowout type spraying method is used for uniformly forming a film. The heterodiamine (diamino dianthryl ether) has a hybridized molecular weight greater than 1,000,000, is subjected to gel synthesis at a temperature of more than −100° C., and is uniformly formed into a film through a blowout type spraying method. The high-density polyimide thick film is prepared by volatilizing a solvent through a blowout apparatus and isolating the solvent from moisture.

The specific preparation method may be referred to the method disclosed in the applicant's prior patent application CN 109776826 A.

In a preferred embodiment, in step S3, when dehydrogenating and denitrifying the film material during a blackleading process, and the nano-metal is doped with the protective gas at a pressure of 50 kPa.

Preferably, two or more of the three protective gases N, Ar, Ne are mixed and used in the carbonization and blackleading treatment, more preferably 50% of N and 50% of Ar are mixed and used in the carbonization, more preferably 50% of Ar and 50% of Ne are mixed and used in the blackleading process. This design is very helpful for oxidation resistance. During carbonization and blackleading process, the mixed protective gas effectively protects the surface from the influences of oxidation and air pressure. High purity neon is also optional in blackleading.

In a preferred embodiment, the nano-metal is selected from Al, Ga, In and Ge, preferably from Ga, In and Ge, with a particle size below 1,000 nm, preferably below 400 nm.

In step S03, carbonizing and blackleading the polyimide thin film, doping nano-metal to the polyimide thin film, and performing ion implantation and ion exchange, wherein a nano monoclinic crystal phase in the film is changed into a tetragonal crystal, and the single crystal is changed into a superlattice. Specifically, a full-automatic continuous carbonization and blackleading furnace is adopted, the polyimide thin film passes through a preheating area, a heating and constant-temperature heating area and a cooling area in the process, so that the ion implantation and ion exchange time meets the set process requirement, which is sequentially and circularly operated through heat sources, protective gas, temperature, time and speed control.

For doping nano-metal, particularly when dehydrogenating and denitrifying during the blackleading process, the nano-metal is doped with the protective gas at a gas pressure of 50 Kpa. The nano-metal is selected from Al, Ga, In and Ge, preferably Ga, In and Ge. The nano-metal has a particle size below 1,000 nm, preferably 400 nm. For ion implantation and ion exchange, during blackleading, the base film starts an expansion period at 2800° C., a single crystal and a monoclinic crystal change, phase a carbon element lattice is complete, the nano-metal is injected during deoxidation, the nano-metal element changes phase from a transition element to a tetragonal lattice, and meanwhile, the single crystal is changed into a superlattice.

In a preferred embodiment, in step S04, an annealing process is performed at a temperature not lower than 3,200° C. to make a base film material expand, deoxidize and replace, transform crystal phase change to meet the high-orientation requirement of the superlattice.

In step S04, in order to reduce the defect grain boundaries and transition from one axis to two axes, the annealing process is preferably performed at an extremely high temperature of 3,200° C. Through cyclic expansion, deoxidation replacement and transformation of crystal phase change, the layered plane direction is aligned with the vertical direction to meet the requirement of high orientation, the superlattice is oriented more than 87%, so that van der waals force is optimized to make the flexible carbon-based film reach a K value of 1900±100 W/m⁻¹k⁻¹, without wrinkle and super elasticity, and fold more than 8000 times at 10% elongation limit, and bent more than 100,000 cycles at 180° C. With a semiconductor carrier concentration up to 1.6×10²⁰, the flexible carbon base film has high thermal conductivity, due, at least in part, to high concentration, core vibration of particles in the crystal lattice, scaling of domain size, formation of interfacial boundary pores, it has high crystallinity and reduced defect grain boundaries, has a thermal conductivity K value reaches 1488 W/m⁻¹k⁻¹ at a thickness of 30 μm with very limited strain, which realized super flexibility in the range of 0.2%-0.4%.

By preferably using an annealing process with an extremely high temperature not less than 3,200° C., the defective grain boundaries are effectively eliminated. The defect means that there is no defect in oxygen-containing functional groups, nanocavities and SP₃ carbon bonds on the surface of the compound semiconductor C-C-X base film. The crystal in the super-elastic carbon-carbon-hybrid alkene sheet can be folded, with the large elongation adapt to the external tension, it can provide sufficient degree of freedom for bending deformation. At the same time, high temperature annealing reduces the phonon scattering center, the defects in the lattice structure and in the functional groups of carbon-carbon-X base films.

In other preferred embodiments, step S1 comprises: firstly, performing plasma modification treatment on the surface of the quantum carbon-based film, preferably argon plasma, and generating an acrylic acid grafted layer on the surface of the quantum carbon-based film through a grafting reaction; depositing on the surface of the quantum carbon-based film to form the PI film.

The quantum carbon-based film can also be obtained from the above embodiments, or with reference to the method disclosed in the applicant's prior patent application CN 109776826 A.

Preferably, step S1 comprises the steps of:

performing plasma modification treatment on the surface of the quantum carbon-based film;

performing CVD vapor deposition reaction on the surface of the quantum carbon-based film to obtain a PI film;

performing rapid thermal treatment of PI films formed by CVD deposition.

The argon plasma modification treatment process of the quantum carbon-based film comprises the steps of:

(1) placing the quantum carbon-based film in acetone solution or anhydrous ethanol, cleaning with ultrasonic waves, and then vacuum drying in a vacuum drying box;

(2) performing argon plasma treatment after the treatment is finished, the plasma treatment power is 20-150 W, the working pressure is 10-100 Pa, and the treatment time is 5-30 min. Preferably, the discharge power is 70 W, the discharge time is 15 min, and the working pressure is 70 Pa; and

(3) after performing surface modification of the quantum carbon-based film by plasma, the surface of the quantum carbon-based film is grafted by a chemical treatment method, so that the bonding property of the quantum carbon-based film can be improved. The chemical treatment method is to subject the plasma treated quantum carbon-based film to grafting reaction in an acrylic acid solution.

The specific procedure is to immerse the quantum carbon-based film treated by plasma in an acrylic acid solution, followed by heating in a 40° C. water bath for 5-6 h. After completion, the surface of the film is rinsed with distilled water, and the film is immersed in distilled water and heated in a water bath at 60° C. for 24 h. After completion, the lamina is vacuum dried. The acrylic acid solution has a volume concentration of 2-10%. Preferably the concentration of the acrylic acid solution is 4%;

The vapor deposition reaction of the PI film on the surface of the quantum carbon-based film comprises the steps of:

(1) Evaporating a monomer dianhydride precursor in a glass crucible of a reactor at a certain evaporation temperature, wherein the reactor pressure is 2-3 mbar, sending to the surface of the quantum carbon-based film treated by argon plasma in S1 in the form of gas pulse through a nitrogen valve, wherein the pulse time is 1.5-7.0 s, preferably 3.0 s; the monomeric dianhydride precursor may be one or a combination of several of 3, 3′,4,4′-biphenyltetracarboxylic dianhydride, 2,3,3′,4′-diphenyl ether tetracarboxylic dianhydride, 3, 3′,4,4-diphenyl ether tetracarboxylic dianhydride, or 2,2-bis (3,4-dicarboxyphenyl) hexafluoropropionic dianhydride.

(2) Nitrogen purging, purging time: 1.5-3.0 s;

(3) Evaporating a monomer diamine precursor in a glass crucible of a reactor at a certain evaporation temperature, wherein the reactor pressure is 2-3 mbar, sending to the surface of the quantum carbon-based film treated by argon plasma in S1 in the form of gas pulse through a nitrogen valve, and reacting with a dianhydride precursor which is chemisorbed on the surface of the quantum carbon-based film, wherein the pulse time is 1.0-5.0 s, preferably 2.0 s; the monomeric diamine precursor can is one or a combination of several of m-phenylenediamine, p-phenylenediamine, 3, 3′-diaminodiphenyl ether, 3, 4′-diaminodiphenyl ether, 3, 3′-diaminotoluene, 3, 3′-diaminediphenyl sulfone or 4, 4′-diamine diphenyl sulfone.

(4) Nitrogen purging, purging time: 1.5-3.0 s.

Steps (1) to (4) are one deposition cycle (dianhydride-nitrogen-diamine-nitrogen), after which the above cycle is repeated, the thickness of the deposited film is controlled by the number of cycles.

The rapid thermal treatment of the CVD deposited PI film, the PI film just deposited is subjected to thermal treatment in a rapid thermal annealing furnace (RTA) so as to completely imidize and eliminate an internal stress of the deposited film, and the annealing is performed in a nitrogen atmosphere fora time of 10 min at a thermal treatment temperature of 200-350° C.

According to the preferred embodiment described above, the reaction of gaseous species at the gas phase or gas-solid interface to form a solid thin film material is performed by chemical vapor deposition (CVD) on the quantum carbon-based surface layer using the steps described above. The thin film material comprises a thermosetting resin doped with a high frequency, low dielectric polyimide resin. During chemical vapor deposition (CVD), monomer dianhydride precursor resin and monomer diamine react alternately, and a thermosetting resin thin film is synthesized by chemical vapor deposition doped with low dielectric inorganic to obtain a flexible circuit board (C-FPC) base material based on a quantum carbon-based film. The experimental results show that the material has uniform surface distribution, smooth appearance, roughness within 2 nm, no peeling, bending strength ≥130 mpa, high frequency of 10 GHz, dielectric constant ≤2±0.03, insertion loss ≤0.2 DB/inch, thermal decomposition temperature ≥300° C., thermal conductivity 1400 W/m⁻¹k⁻¹, coefficient of thermal expansion ≤19 ppm/° C.

According to the preferred embodiment, the deposited PI film is uniform in thickness, smooth in appearance, good in bonding force with the quantum carbon-based film and controllable in thickness, and has obvious advantages in uniformity, shape preservation, step coverage rate, thickness control and the like of the film layer.

The prepared PI thin film has the advantages of being controllable in thickness, better in uniformity and surface flatness, free of solvent pollution or interference, capable of depositing a film on the surface of a complex structure and the like, and has great strengths in preparation of planar films and microspheres.

The outstanding beneficial effects are, inter alia, the following:

(1) The argon plasma treatment surface modification treatment is performed on the surface of the quantum carbon-based film, so that the bonding strength between the PI film and the quantum carbon-based film is greatly improved.

In the plasma state, after plasma treatment is performed on the surface of the quantum carbon-based film by using inert gas argon, a large amount of peroxy radicals are generated on the surface of the film, and the peroxy radicals ROO. will react with acrylic acid as follows: ROO.+CH₂═CHCOOH→ROO—CH═CHCOOH, so that an acrylic acid grafted layer can be generated on the surface of the quantum carbon-based film, and the acrylic acid grafted layer is hydrophilic, thus the possibility of reducing the contact angle and improving the bonding strength of the surface of the quantum carbon-based film is provided.

(2) Depositing PI thin films on the surface of quantum carbon films by CVD, the PI thin films with uniform deposition, controllable film thickness and close composition to strict stoichiometric ratio can be obtained.

During CVD, thin films are deposited by alternating saturated pulses of precursor gases with inert gas purging at intervals. Complementarity and self-limiting of surface reactions are the two most important features of CVD, which in turn determine the controllability of film thickness and the correct stoichiometric ratio.

(3) The conductor copper foil layer in the traditional FCCL can be replaced by quantum carbon-based film, and the carbon-based circuit board manufactured has good thermal and electrical conductivity, large specific heat, excellent heat resistance, low temperature rises when large current passes, no fusing, with greatly improved reliability, which is particularly suitable for manufacturing small-size high-power devices.

By adopting the preferred technical embodiment, the PI thin film deposited by the CVD method is uniformly distributed on the surface area of the whole quantum carbon-based film, the appearance is smooth, the thickness tolerance is not more than 5%, the roughness is not more than 2 nm, the bonding force with the quantum carbon base film is good, no peeling or shedding occurs in the tape test, and the film thickness can be flexibly controlled by adjusting the deposition cycle times.

Preferred embodiments and effects thereof are further described below.

### Example 1

Raw Materials:

3,3′,4,4′-biphenyltetracarboxylic dianhydride

m-phenylenediamine

nitrogen (carrier gas/purge gas)

quantum carbon-based films (thickness: 20 μm)

water vapor

Instrument:

CVD vapor deposition apparatus (Finland)

PEO601 RTA rapid thermal annealing furnace (Germany)

Preparation Steps:

S1: performing argon plasma modification treatment on the surface of the quantum carbon-based film, comprising the steps of:

(1) placing the quantum carbon-based film in acetone solution or anhydrous ethanol, cleaning with ultrasonic waves, and then vacuum drying in a vacuum drying box;

(2) performing argon plasma treatment after the treatment is finished, the plasma treatment power is 70 W, the working pressure 70 Pa, and the treatment time is 15 min; and

(3) After performing surface modification of the quantum carbon-based film by plasma, the surface of the quantum carbon-based film is grafted by a chemical treatment method, so that the bonding property of the quantum carbon-based film can be improved. The chemical treatment method is to subject the plasma treated quantum carbon-based film to grafting reaction in an acrylic acid solution. The specific procedure is to immerse the quantum carbon-based film treated by plasma in an acrylic acid solution, followed by heating in a 40° C. water bath for 5-6 h. After completion, the surface of the film is rinsed with distilled water, and the film is immersed in distilled water and heated in a water bath at 60° C. for 24 h. After completion, the lamina is vacuum dried. The concentration of the acrylic acid solution is 4%.

S2: performing ALD deposition reaction of the PI film on the surface of the quantum carbon-based film, comprising the steps of:

(1) Evaporating 3,3′,4,4′-biphenyltetracarboxylic dianhydride precursor in a glass crucible of a reactor at an evaporation temperature of 160° C., wherein the reactor pressure is 2-3 mbar, sending to the surface of the quantum carbon-based film treated by plasma in S1 in the form of gas pulse through a nitrogen valve, wherein the pulse time is 3.0 s;

(2) Nitrogen purging, purging time: 1.5-3.0 s;

(3) Evaporating a m-phenylenediamine precursor in a glass crucible of a reactor at a evaporation temperature of 150° C., wherein the reactor pressure is 2-3 mbar, sending to the surface of the quantum carbon-based film treated by plasma in S1 in the form of gas pulse through a nitrogen valve, and reacting with a dianhydride precursor which is chemisorbed on the surface of the copper foil, wherein the pulse time is 2.0 s;

(4) Nitrogen purging, purging time: 1.5-3.0 s.

The above (1) to (4) are one deposition cycle (dianhydride-nitrogen-diamine-nitrogen), after which the above cycle is repeated, the thickness of the deposited film is controlled by the number of cycles. For ease of comparison, the number of cycles in the present invention is uniformly 1,000.

S3: performing rapid thermal treatment of PI films deposited by CVD vapor deposition

performing thermal treatment on the PI film just deposited in S2 in a rapid thermal annealing furnace (RTA) to completely imidize and eliminate an internal stress of the deposited film, and performing annealing in a nitrogen atmosphere for a time of 10 min, at a temperature of 200-350° C.

### Example 2

The difference from Example 1 is: this is a CVD vapor deposition of PI prepared from monomer raw materials 2,3,3′,4′-diphenyl ether tetracarboxylic dianhydride and 3,3′-diaminodiphenyl ether on the surface of quantum carbon-based film, the deposition cycle and the reaction conditions are as follows: 2,3,3′,4′-diphenyl ether tetracarboxylic dianhydride gas pulses (deposition temperature: 170° C., pulse time: 3.0 s)—N₂ (purging time: 1.5-3.0 s)—3, 3′-diaminodiphenyl ether gas pulse (deposition temperature: 150° C., pulse time: 2.0 s)—N₂ (purging time: 1.5-3.0 s). The rest is the same as in Example 1.

### Example 3

The difference from Example 1 is: this is a CVD deposition of PI prepared from monomer raw materials 2,3,3′,4′-diphenyl ether tetracarboxylic dianhydride and 3,3′-diaminediphenyl sulfone on the surface of quantum carbon-based film, the deposition cycle and the reaction conditions are as follows: 3,3′,4,4-diphenyl ether tetracarboxylic dianhydride gas pulses (deposition temperature: 141° C., pulse time: 3.0 s)—N₂ (purging time: 1.5-3.0 s) —3,3′-diaminediphenyl sulfone gas pulse (deposition temperature: 100° C., pulse time: 2.0 s)—N₂ (purging time: 1.5-3.0 s). The rest is the same as in Example 1.

### Example 4

The difference from Example 1 is: this is a ALD deposition of PI prepared from monomer raw materials 3,3′,4,4-diphenyl ether tetracarboxylic dianhydride and 4,4′-diaminediphenyl sulfone on the surface of quantum carbon-based film, the deposition cycle and the reaction conditions are as follows: 3,3′,4,4-diphenyl ether tetracarboxylic dianhydride gas pulses (deposition temperature: 128° C., pulse time: 3.0 s)—N₂ (purging time: 1.5-3.0 s) —4,4′-diaminediphenyl sulfone gas pulse (deposition temperature: 154° C., pulse time: 2.0 s)—N₂ (purging time: 1.5-3.0 s). The rest is the same as in Example 1.

The product properties obtained from the above four examples are shown in the following table:

| | | Exam- | Exam- | Exam- | Exam- |
|---|---|---|---|---|---|
| | | ple 1 | ple 2 | ple 3 | ple 4 |
| Conductor | Volume resistivity | 0.1 | | | |
| layer | (mΩ · cm) | | | | |
| (quantum | Flex resistance | ≥1,500 times | | | |
| carbon- | property | | | | |
| based | Thermal | ≥1,200 | | | |
| film) | conductivity | | | | |
| | (W/m · K) | | | | |
| Insulating | Deposition rate | 4.9 | 4.3 | 5.6 | 6.1 |
| layer (PI | (Å/cycle) | | | | |
| film) | Deposited film | 22 | 19 | 25 | 27 |
| | thickness@45000 | | | | |
| | cycles (μm) | | | | |
| | Thickness tolerance | <5% | <5% | <5% | <5% |
| | Roughness (nm) | <2 | <2 | <2 | <2 |
| | Peel strength | Tape | Tape | Tape | Tape |
| | | test | test | test | test |
| | | pass | pass | pass | pass |
| | Surface | 1.6 × | 1.5 × | 1.8 × | 1.7 × |
| | resistance (Ω) | 10¹⁴ | 10¹⁴ | 10¹⁴ | 10¹⁴ |
| | Coefficient of | ≤20 | ≤20 | ≤20 | ≤20 |
| | thermal expansion | | | | |
| | (ppm/° C.) | | | | |
| | T_{g} (° C.) | 350 | 368 | 380 | 375 |
| | Elastic modulus | 5.62 | 5.38 | 5.87 | 5.69 |
| | (GPa) | | | | |

The test results show that by replacing the conductor copper foil in the conventional FCCL with the quantum carbon-based film, the manufactured carbon-based film has the characteristics of good thermal and electrical conductivity and excellent bending resistance. Meanwhile, by adopting the CVD method to deposit the PI thin film, the PI thin film deposited by the CVD method is uniformly distributed on the surface area of the whole quantum carbon-based film, the appearance is smooth, the thickness tolerance is not more than 5%, the roughness is not more than 2 nm, the bonding force with the quantum carbon base film is good, no peeling or shedding occurs in the tape test, and the film thickness can be flexibly controlled by adjusting the deposition cycle times. And the deposited PI film has good heat resistance and good dimensional stability, low thermal expansion coefficient and good insulating property.

### Comparative Example 1

The only difference from Example 1 is: the surface of the quantum carbon-based film is not subjected to plasma modification treatment, and is directly used for CVD deposition of PI after being dried. The results show that there is obvious peeling or shedding phase of PI deposited thin film from the surface of quantum carbon film in the tape test, which indicates that the bonding force between PI film and quantum carbon film is weak. Since the surface of the quantum carbon-based film which has not been plasma-treated is more hydrophobic, it shows less binding force macroscopically.

In a preferred embodiment, the flexible circuit board base material of the manufactured quantum carbon-based film/PI (20 μm/20 μm) double-layer composite structure is a C-C-FPC flexible circuit substrate or a C-C-FCCL substrate material having high electrical conductivity, ultra-flexibility, high thermal conductivity and high frequency characteristics.

In a specific embodiment, the method for manufacturing the high-frequency ultramicro circuit by laser etching on the substrate material comprises the following specific steps of:

(1) Cleaning treatment: cleaning the quantum carbon-based film;

(2) Determining a scanning track: contour processing is performed on a circuit board wire graph by using a data computer, and the graph is drawn in an Auto-CAD document format;

(3) Importing the drawn Auto-CAD document into a laser, and placing the flexible circuit board base material based on a flexible carbon-based film on a laser carrier/stage;

(4) Setting laser parameters: the laser output energy is 0.5-1.0 J/cm², and the laser scanning speed is 50-300 mm/s, performing laser scanning etching according to parameters, and manufacturing a high-frequency ultramicro antenna circuit based on the ultrathin adhesiveless carbon-based flexible base material.

The optimal laser energy density is 0.8 J/cm², laser scanning speed is 100 mm/s, line width/line spacing is 5 nm/5 nm.

The foregoing is a further detailed description of the present invention in connection with specific/preferred embodiments, and is not to be construed as limiting the present invention to such specific embodiments. It will be apparent to those skilled in the art that various substitutions and modifications can be made to the described embodiments without departing from the spirit of the present invention, and it is intended that such substitutions and modifications fall within the scope of the present invention. In the description of this specification, reference to the description of the terms “one embodiment”, “some embodiments”, “preferred embodiments”, “examples”, “specific examples”, or “some examples”, etc., means that a particular feature, structure, material, or characteristic described in connection with the embodiment or example is included in at least one embodiment or example of the present invention. In the present specification, schematic expressions of the above terms are not necessarily directed to the same embodiments or examples. Furthermore, the particular features, structures, materials, or characteristics described may be combined in any one or more embodiments or examples in a suitable manner. Moreover, various embodiments or examples described in this specification, as well as features of various embodiments or examples, may be incorporated and combined by those skilled in the art without departing from the scope of the invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A preparation method of an ultramicro circuit board based on an ultrathin adhesiveless flexible carbon-based material, comprising the steps of:
S1. depositing to form a PI film on a surface of a quantum carbon-based film through a chemical vapor deposition (CVD) reaction, and manufacturing a flexible circuit board base material with a quantum carbon-based film/PI double-layer composite structure; and
S2. manufacturing a high-frequency ultramicro circuit antenna on the flexible circuit board base material through a laser scanning etching method.

2. The preparation method of the ultramicro circuit board of claim 1, wherein when the high-frequency ultramicro circuit antenna is manufactured in the step S2, a laser energy density is controlled to be 0.5-1.0 J/cm², preferably 0.8 J/cm², and a laser scanning speed is controlled to be 50-300 mm/s, preferably 100 mm/s; preferably, a circuit line width/line spacing is 5 nm/5 nm; preferably, an antenna ultramicro circuit is etched in alignment by rapidly moving a beam through a scanning galvanometer, and non-contact analog imaging is employed.

3. The preparation method of the ultramicro circuit board of claim 1, further comprising the step of manufacturing the quantum carbon-based film before the step S1:
S01. hybridizing anhydride containing phenyl with diamine to obtain a thermoplastic polyimide resin precursor;
S02. preparing a polyimide thin film by using the thermoplastic polyimide resin precursor;
S03. carbonizing and blackleading the polyimide thin film, doping nano-metal to the polyimide thin film, and performing ion implantation and ion exchange, wherein a nano monoclinic crystal phase in the film is changed into a tetragonal crystal, and the single crystal is changed into a superlattice; and
S04. performing high-temperature annealing treatment on the material obtained in the step S03 to generate a super-flexible ultra-thin compound semiconductor film.

4. The preparation method of the ultramicro circuit board of claim 3, wherein in the step S02, a diamino dianthryl ether is used for gel synthesis with the thermoplastic polyimide resin precursor, and a blowout type spraying method is used for uniformly forming a film to obtain a heterogeneous hybridized polyimide thin film; preferably, the gel synthesis is performed above −100° C., preferably the diamino dianthryl ether has a hybridized molecular weight greater than 1,000,000.

5. The preparation method of the flexible carbon-based film of claim 3, wherein in the step S03, when dehydrogenating and denitrifying during a blackleading process, nano-metal is doped with a protective gas at a pressure of 50 Kpa, and the nano-metal is selected from Al, Ga, In and Ge, preferably from Ga, In and Ge, with a particle size of 1,000 nm or less, preferably 400 nm or less.

6. The preparation method of the flexible carbon-based film of claim 3, wherein in the step S04, an annealing process is performed at a temperature not lower than 3,200° C. to make a base film material expand, deoxidize and replace, transform crystal phase change to meet the high-orientation requirement of the superlattice.

7. The preparation method of the ultramicro circuit board of claim 1, wherein the step S1 comprises: firstly performing plasma modification treatment on a surface of the quantum carbon-based film, preferably argon plasma, and generating an acrylic acid grafted layer on the surface of the quantum carbon-based film through a grafting reaction; and then depositing on the surface of the quantum carbon-based film to form the PI film;
preferably, a plasma treatment discharge power is 20-150 W, a working air pressure is 10-100 Pa, and a treatment time is 5-30 min; preferably, the discharge power is 70 W, the working pressure is 70 Pa, and the treatment time is 15 min;
preferably, generating the acrylic graft layer comprises: immersing the quantum carbon-based film subjected to plasma treatment into an acrylic acid solution with a volume concentration of 2%-10% for grafting reaction; preferably, the concentration of the acrylic acid solution is 4%; preferably, the surface of the film is rinsed with distilled water after being immersed in the acrylic acid solution and heated in a 40° C. water bath for 5-6 h, then the film is immersed in distilled water, and after being heated in a 60° C. water bath for 24 h, the quantum carbon-based film is vacuum dried.

8. The preparation method of claim 1, wherein the step S1 further comprises: performing rapid thermal treatment on the formed PI film to completely imidize the PI film and eliminate an internal stress of the PI film; preferably, performing rapid thermal treatment on the freshly deposited PI film in a rapid thermal annealing (RTA) furnace in an inert gas atmosphere, preferably nitrogen, for 10 min at a thermal treatment temperature of 200-350° C.

9. The preparation method of claim 1, wherein in the step S1, depositing to form the PI film comprises: alternately depositing a monomer dianhydride precursor and a monomer diamine precursor on the surface of the quantum carbon-based film, and performing cyclic deposition, wherein a thickness of the deposited film is controlled by controlling the number of cycles of deposition; preferably, the monomeric dianhydride precursor is one or a combination of several of 3,3′,4,4′-biphenyltetracarboxylic dianhydride, 2,3,3′,4′-diphenyl ether tetracarboxylic dianhydride, 3,3′,4,4-diphenyl ether tetracarboxylic dianhydride and 2, 2-bis (3,4-dicarboxyphenyl) hexafluoropropionic dianhydride; the monomeric diamine precursor is one or a combination of several of m-phenylenediamine, p-phenylenediamine, 3,3′-diaminodiphenyl ether, 3,4′-diaminodiphenyl ether, 3,3′-diaminotoluene, 3,3′-diaminediphenyl sulfone and 4,4′-diamine diphenyl sulfone; preferably, one deposition cycle comprises the steps of:
S11. sending the evaporated monomer dianhydride precursor to the surface of the quantum carbon-based film in the form of an inert gas pulse, preferably nitrogen pulse for a pulse period of 1.5-7.0 s, preferably 3.0 s, and at a reactor pressure of 2-3 mbar; and
S12. sending the evaporated monomer diamine precursor to the surface of the quantum carbon-based film in the form of an inert gas pulse, preferably nitrogen pulse, and reacting with a dianhydride precursor which is chemisorbed on the surface of the quantum carbon-based film for a pulse time of 1.0-5.0 s, preferably 2.0 s, and at a reactor pressure of 2-3 mbar;
more preferably, after steps S11 and 12, an inert gas purge, preferably nitrogen purge, is performed before the next step, preferably a purging time is 1.5-3.0 s.

10. An ultramicro circuit board based on an ultrathin adhesiveless flexible carbon-based material, being an ultramicro circuit board prepared by using the method of claim 1.
